(19) United States
(12) Patent Application Publication
(10) Pub. No.: US 2016/0346929 A1
(43) Pub. Date: Dec. 1, 2016

(54) ROBOT CALIBRATION TOOLKIT

(71) Applicant: Kawasaki Robotics (USA), Inc., Wixom, MI (US)

(72) Inventors: Zhengyuan Sam Yang, Wixom, MI (US); Brian Carpenter, Wixom, MI (US); René David Alfaro, Wixom, MI (US)

(21) Appl. No.: 14/721,979

(22) Filed: May 26, 2015

(51) Int. Cl. B25J 9/16; G01R 19/165; G01L 5/22

(52) U.S. Cl. CPC B25J 9/1692; G01L 5/226; G01R 19/16528; Y10S 901/02; Y10S 901/41

(57) ABSTRACT

A robot calibration system may comprise a robot with an end-of-arm tool for industrial manufacturing, an output sensor to measure an output of the robot, and a computing device running a calibration program for calibrating the robot. The calibration program may comprise a communication module to receive output data from the output sensor, and a control module to command the robot. The control module may be configured to command actuation of the end-of-arm tool at an initial input value of an electrical parameter, determine that a current output value is not within a threshold of a target value, execute an interpolation algorithm to calculate a next input value, command actuation at the next input value, determine that the current output value is within the threshold of the target value, end calibration, and log a relationship between input values and corresponding output values.

### BACKGROUND

Robots are commonly used in industrial manufacturing environments to complete tasks with high speed, strength, and precision. In order to perform under these conditions, such robots are often calibrated by trained operators with long and complicated calibration processes. One type of robot with a servo gun used for welding takes around eight hours to calibrate for various welding positions and target values, and each operator can only calibrate one robot at a time. The operator uses a teach pendant that typically includes many menu screens into which calculated values are inputted by the operator. Calculating the values sometimes includes reading graphs and estimation on the part of the operator. Not only does this approach take considerable time, but it also introduces the possibility of human error to the calibration.

### SUMMARY

Methods and systems disclosed herein include a robot calibration system which may comprise a robot with an end-of-arm tool for industrial manufacturing, an output sensor configured to measure an output of the robot, and a computing device running a calibration program for calibrating an operation of the robot. The calibration program may comprise a communication module configured to receive output data from the output sensor and status data from the robot, and a control module configured to receive user input and to command the robot. The control module may be configured to contact the robot to initiate calibration, command actuation of the end-of-arm tool at an initial input value of an electrical parameter, identify a current output value in the output data from the communication module, determine that the current output value is not within a threshold of a target value, execute an interpolation algorithm to calculate a next input value of the electrical parameter, command actuation of the end-of-arm tool at the next input value, identify a new current output value in the output data, determine that the new current output value is within the threshold of the target value, command the robot to end calibration, log a relationship between input values of the electrical parameter and corresponding output values of the output sensor, and make the logged relationship available to the robot to perform the calibrated operation according to the logged relationship.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to implementations that solve any or all disadvantages noted in any part of this disclosure.

### BRIEF DESCRIPTION OF THE DRAWINGS

FIG. 1 is a simplified schematic diagram of a robot calibration system according to one embodiment.

FIG. 2 is a simplified schematic diagram of the robot calibration system according to another embodiment.

FIG. 3 shows a flowchart of a method of calibrating an operation of a robot.

FIG. 4 is a simplified schematic diagram of a computing system.

### DETAILED DESCRIPTION

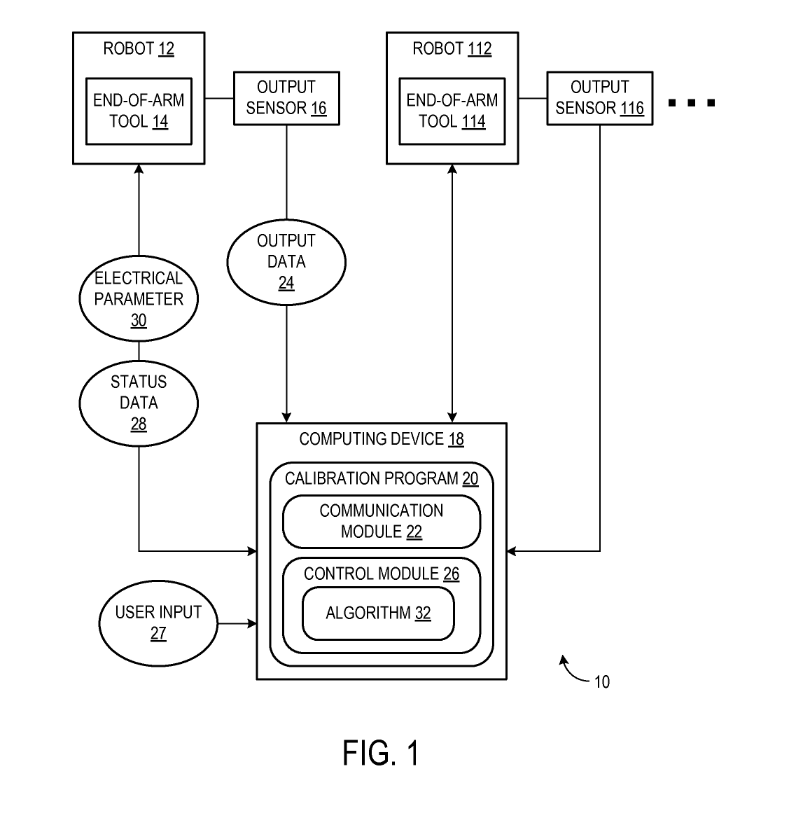

FIG. 1 is a simplified schematic diagram of a robot calibration system 10 according to one embodiment. The robot calibration system 10 may comprise a robot 12 with an end-of-arm tool 14 for industrial manufacturing and at least one output sensor 16 configured to measure an output of the robot 12. The robot calibration system 10 may further comprise a computing device 18 running a calibration program 20 for calibrating an operation of the robot 12. The computing device 18 may be a personal computer, laptop computer, tablet computer, smartphone, etc. Typically, the computing device 18 includes a processor such as a central processing unit, a system-on-chip, or another suitable type of processor, as described in more detail below. The calibration program 20 may comprise a communication module 22 configured to receive output data 24 from the output sensor 16 and status data 28 from the robot 12, and a control module 26 configured to receive user input 27 and to command the robot 12.

The control module 26 may be configured to contact the robot 12 to initiate calibration, then command actuation of the end-of-arm tool 14 at an initial input value of an electrical parameter 30. The control module 26 may identify a current output value in the output data 24 from the communication module. The control module 26 may then compare the current output value to a target value. Once the control module 26 determines that the current output value is not within a threshold of the target value, it may then execute an interpolation algorithm 32 to calculate a next input value of the electrical parameter 30 and command actuation of the end-of-arm tool at the next input value. The interpolation algorithm 32 may calculate the next input value of the electrical parameter 30 through tangential interpolation.

Calibration may take several such iterations before a satisfactory output value is achieved. The control module 26 may identify a new current output value in the output data, determine that the new current output value is within the threshold of the target value, and command the robot to end calibration. Finally, the control module 26 may log a relationship between input values of the electrical parameter 30 and corresponding output values of the output data 24 and make the logged relationship available to the robot to perform the calibrated operation according to the logged relationship. The logged relationship may be used later to accurately actuate the end-of-arm tool 14 without first calibrating the robot 12 again. The relationship may be logged as a text file of paired input and output data points, for example, or a formula derived therefrom. The relationship may be linear, but may also be non-linear. Included with the logged relationship may also be the status data 28.

The end-of-arm tool 14 may be a servo gun, gripper, vacuum cup, magnet, or clamp, for example. The electrical parameter 30 may be an electrical characteristic, such as an amperage, voltage, etc., of electrical power supplied to the end-of-arm tool 14 when actuation is commanded. The output sensor 16 may be a force sensor, and the output data 24 may be force data, for example. The output data 24 may also be a pressure, a temperature, a joint position, or a joint angle, generated by a suitable sensor as the output sensor 16, among other examples.

The user input 27 may be stored in advance to indicate the target value and the robot calibration system 10 may be automated such that no additional user input 27 is received during calibration. In such a case, the robot calibration system 10 may be an automatic robot calibration system. Alternatively, the robot calibration system 10 may be configured with break points for accepting user input to ensure safety. The target value may be one value in a table of various target values, and the calibration process may be performed for each target value in the table. The target values in the table may be inputted by an operator, preset by a robot service provider, calculated by the computing device 18 based on programmed instructions, or retrieved from a previous calibration or operation. The threshold may be preset by the operator or robot service provider, for example at ±5%, and it may be adjustable.

The robot 12 may be one of a plurality of robots contacted by the control module 26, and the output sensor 16 may be one of a plurality of output sensors each associated with one of the plurality of robots. For example, FIG. 1 illustrates a robot 112 with an end-of-arm tool 114 and output sensor 116, and the ellipsis indicates more of the same (that is, additional similarly configured robots) in contact with the computing device 18. The calibration of any of the plurality of robots may overlap in time or be in quick succession and may be performed by a single operator. In one example for the sake of illustration, one iteration in calibration may take approximately 10 seconds, and an output value within the threshold of the target value may be reached within three to five iterations, all with minimal to no real-time user input. The fast calibration combined with the multiple robots per operator capability may lend the robot calibration system 10 great advantage over traditional systems.

The status data 28 may include any of a joint angle, a joint position, a joint speed, a joint motor amperage, a robot position, and a robot speed, for example. The status data 28 may be taken into account when logging the relationship because the status of the robot 12 may affect the output data 24. For instance, a force calibration may be repeated for each of several robot positions because gravity may have a greater or lesser component in the direction of the force being applied by the end-of-arm tool depending on the robot position. If the target value is one value in the table of various target values, then the various target values may be at different statuses of the robot 12 as well.

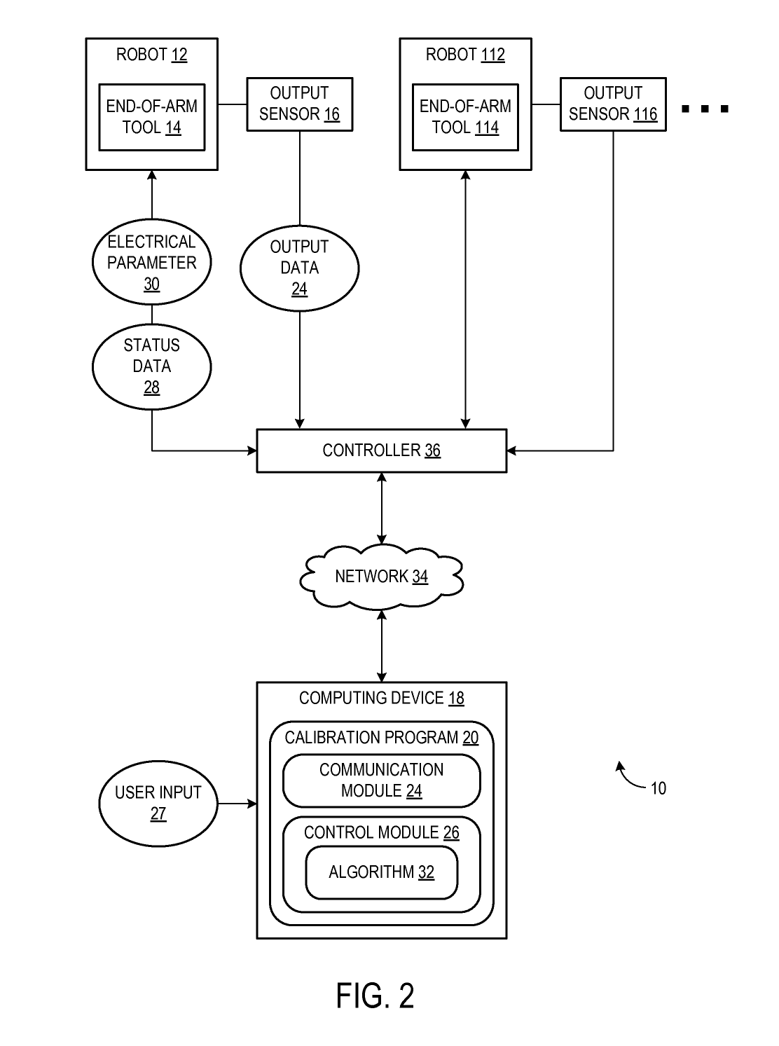

FIG. 2 is a simplified schematic diagram of the robot calibration system according to another embodiment. Descriptions of components also present in the system 10 of FIG. 1 will not be repeated. In FIG. 2, the computing device 18 may be a remote computing device such as a laptop computer, smartphone, tablet computer, etc., such that calibration may be controlled remotely. The computing device 18 may be connected to the robot via a network 34 and a controller 36. Regardless of the type, the computing device 18 may be removable from the robot calibration system 10 once calibration has completed and the robot 12 is to begin or resume normal operation. In this way, the robot calibration system 10 may be adopted with minimal additional hardware. The computing device 18 may also be left integrated with the robot calibration system 10 during normal operation.

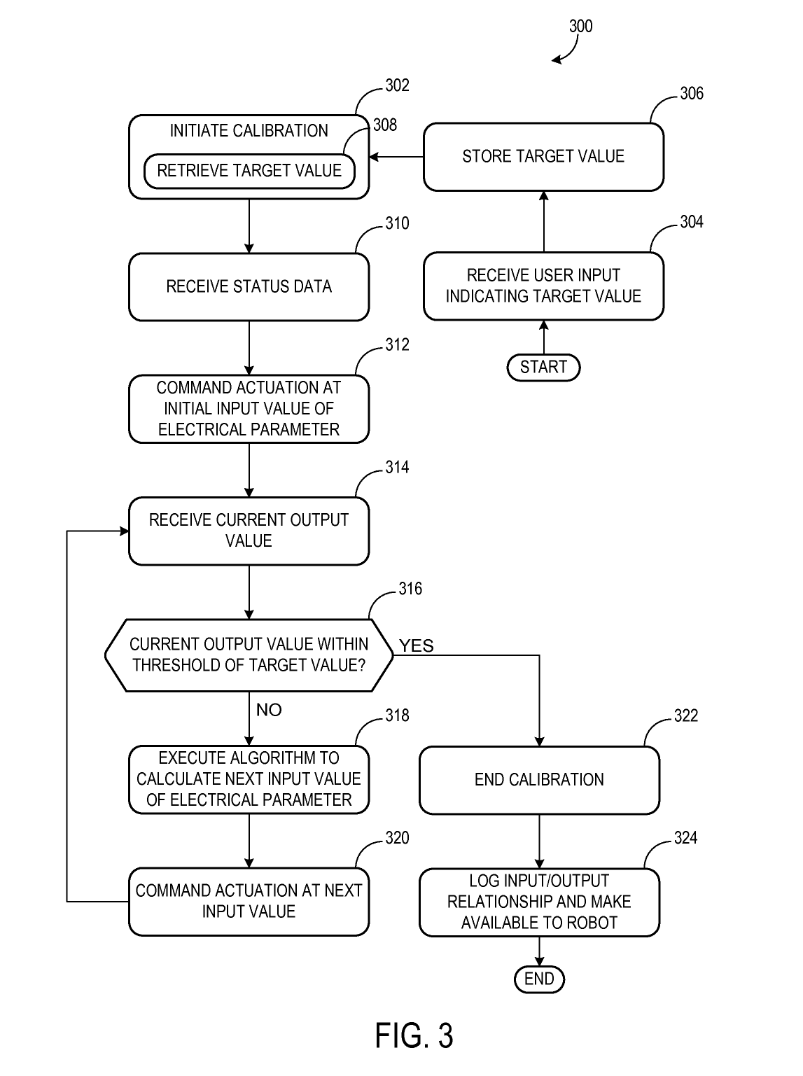

FIG. 3 illustrates a flowchart of a method 300 for calibrating an operation of a robot with an end-of-arm tool for industrial manufacturing using a computing device running a calibration program. The following description of method 300 is provided with reference to the various components of the robot calibration system 10 described above and shown in FIGS. 1 and 2. It will be appreciated that method 300 may also be performed in other contexts using other suitable hardware and software components. The computing device may be a remote computing device connected to the robot via a network and controller, or the computing device may be a local computing device such as a system-on-chip, for example.

With reference to FIG. 3, at 302, the method 300 may include contacting the robot to initiate calibration. The robot calibration system may be configured to run automatically or to receive user input. If user input is received, at 304, the method 300 may optionally include receiving user input indicating the target value, then storing the target value in memory of the computing device at 306. Upon initiation of calibration at 302, the method 300 may also include retrieving the target value at 308. The target value may be used to calculate an initial input value for the first iteration of calibration. When user input is received in this manner, additional user input may be received throughout calibration, or no additional user input may be received during calibration. As mentioned above, the user input may be provided at break points to ensure safety and greater control over the calibration process. However, the calibration may be automatic such that less human oversight is preferred.

At 310, the method 300 may optionally include receiving status data from the robot, the status data including any of a joint angle, a joint position, a joint speed, a joint motor amperage, a robot position, and a robot speed. The status data may be associated with the input values and/or output values. At 312, the method 300 may include commanding actuation of the end-of-arm tool at the initial input value of an electrical parameter via a control module of the calibration program. At 314, the method 300 may include identifying a current output value of output data from a communication module of the calibration program, the output data generated by an output sensor to measure an output of the robot. In one implementation, the robot may be one of a plurality of robots contacted by the control module, the output sensor may be one of a plurality of output sensors each associated with one of the plurality of robots, and the calibration of any of the plurality of robots may overlap in time.

At 316, the method 300 may include comparing the current output value to a target value. When the method 300 includes determining that the current output value is not within a threshold of a target value (NO), at 318, the method 300 may include executing an interpolation algorithm to calculate a next input value of the electrical parameter. At 320, the method 300 may include commanding actuation of end-of-arm tool at the next input value. After 320, the method 300 may include returning to 314 to identify a new current output value in the output data. Steps 312 to 316 may be considered the first iteration or first cycle of calibration. Steps 318, 320, 314, and 316 may be considered one iteration. As many iterations as it takes to reach the target value within a threshold may be performed, typically about three to five.

At 316 again, the method 300 may include determining that the new current output value is within the threshold of the target value (YES). At 322, the method 300 may include commanding the robot to end calibration. Finally, at 324, the method 300 may include logging a relationship between input values of the electrical parameter and corresponding output values of the output sensor, and making the logged relationship available to the robot to perform the calibrated operation according to the logged relationship. In one example, the electrical parameter may be an amperage, the output sensor may be a force sensor, and the output data may be force data. In this case, the end-of-arm tool may be a servo gun. In such a case, the robot receives an electrical signal and applies a force to the output sensor through the servo gun in proportion to the amperage of the electrical signal. The output sensor in such a case may be a separate device or may be integrated with the servo gun or robot. The output data represents the force actually experienced by the servo gun when a given amperage is applied. Among other examples, the output data may also be a pressure, a temperature, a joint position, or a joint angle. Temperature may be used when the robot is used in welding, for example. Joint position and joint angle may be used alone or in combination to monitor the position, location, and pose of the robot. The position and/or angle of any given joint may affect the movement and output of the robot and thus this information may be tracked and calibrated. Whatever the type of output data, the output data is measured by a corresponding sensor or group of sensors positioned on appropriate parts of the robot. In the calibration procedure, the sensors measure actual physical parameters while the robot is under control that should affect those parameters, so that the control can be adjusted.

Common calibration methods for industrial robots are time consuming and prone to human error, and operator training is extensive. The above systems and methods may be included in a robot calibration toolkit capable of automatic or semi-automatic calibration of an industrial robot in a fraction of the time of conventional methods. According to the above, the operator may calibrate robots with much less calculation and chart reading than in typical methods because the automated system may perform the iteration calculations itself. Moreover, one operator may use the toolkit to operate several robots at once or in quick succession, greatly decreasing time spent on calibration and operating costs.

In some embodiments, the methods and processes described herein may be tied to a computing system of one or more computing devices. In particular, such methods and processes may be implemented as a computer-application program or service, an application-programming interface (API), a library, and/or other computer-program product.

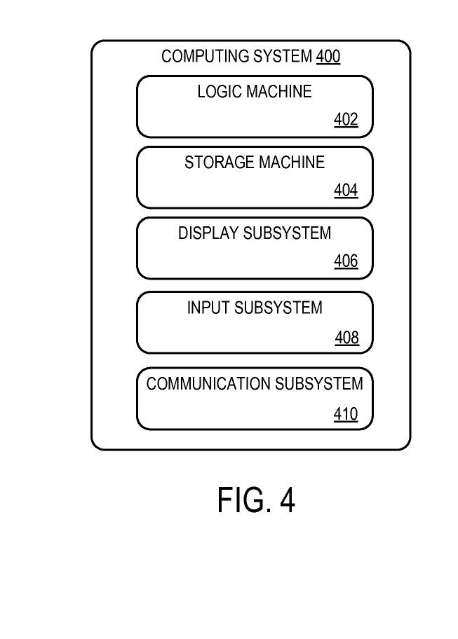

FIG. 4 schematically shows a non-limiting embodiment of a computing system 400 that can enact one or more of the methods and processes described above. Computing system 400 is shown in simplified form. Computing system 400 may take the form of one or more personal computers, server computers, tablet computers, home-entertainment computers, network computing devices, mobile computing devices, mobile communication devices (e.g., smart phone), and/or other computing devices, including the computing device 18 and the controller 36 in the system 10 of FIGS. 1 and 2.

Computing system 400 includes a logic machine 402 and a storage machine 404. Computing system 400 may optionally include a display subsystem 406, input subsystem 408, communication subsystem 510, and/or other components not shown in FIG. 4.

Logic machine 402 includes one or more physical devices configured to execute instructions. For example, the logic machine may be configured to execute instructions that are part of one or more applications, services, programs, routines, libraries, objects, components, data structures, or other logical constructs. Such instructions may be implemented to perform a task, implement a data type, transform the state of one or more components, achieve a technical effect, or otherwise arrive at a desired result.

The logic machine may include one or more processors configured to execute software instructions. Additionally or alternatively, the logic machine may include one or more hardware or firmware logic machines configured to execute hardware or firmware instructions. Processors of the logic machine may be single-core or multi-core, and the instructions executed thereon may be configured for sequential, parallel, and/or distributed processing. Individual components of the logic machine optionally may be distributed among two or more separate devices, which may be remotely located and/or configured for coordinated processing. Aspects of the logic machine may be virtualized and executed by remotely accessible, networked computing devices configured in a cloud-computing configuration.

Storage machine 404 includes one or more physical devices configured to hold instructions executable by the logic machine to implement the methods and processes described herein. When such methods and processes are implemented, the state of storage machine 404 may be transformed—e.g., to hold different data.

Storage machine 404 may include removable and/or built-in devices. Storage machine 404 may include optical memory (e.g., CD, DVD, HD-DVD, Blu-Ray Disc, etc.), semiconductor memory (e.g., RAM, EPROM, EEPROM, etc.), and/or magnetic memory (e.g., hard-disk drive, floppy-disk drive, tape drive, MRAM, etc.), among others. Storage machine 404 may include volatile, nonvolatile, dynamic, static, read/write, read-only, random-access, sequential-access, location-addressable, file-addressable, and/or content-addressable devices.

It will be appreciated that storage machine 404 includes one or more physical devices. However, aspects of the instructions described herein alternatively may be propagated by a communication medium (e.g., an electromagnetic signal, an optical signal, etc.) that is not held by a physical device for a finite duration.

Aspects of logic machine 402 and storage machine 404 may be integrated together into one or more hardware-logic components. Such hardware-logic components may include field-programmable gate arrays (FPGAs), program- and application-specific integrated circuits (PASIC/ASICs), program- and application-specific standard products (PSSP/ASSPs), system-on-a-chip (SOC), and complex programmable logic devices (CPLDs), for example.

The terms “module,” “program,” and “engine” may be used to describe an aspect of computing system 400 implemented to perform a particular function. In some cases, a module, program, or engine may be instantiated via logic machine 402 executing instructions held by storage machine 404. It will be understood that different modules, programs, and/or engines may be instantiated from the same application, service, code block, object, library, routine, API, function, etc. Likewise, the same module, program, and/or engine may be instantiated by different applications, services, code blocks, objects, routines, APIs, functions, etc. The terms “module,” “program,” and “engine” may encompass individual or groups of executable files, data files, libraries, drivers, scripts, database records, etc. An application program may be executable across multiple user sessions, and may be available to one or more system components, programs, and/or other application programs. In some implementations, an application program may run on one or more server-computing devices.

When included, display subsystem 406 may be used to present a visual representation of data held by storage machine 404. This visual representation may take the form of a graphical user interface (GUI). As the herein described methods and processes change the data held by the storage machine, and thus transform the state of the storage machine, the state of display subsystem 406 may likewise be transformed to visually represent changes in the underlying data. Display subsystem 406 may include one or more display devices utilizing virtually any type of technology. Such display devices may be combined with logic machine 402 and/or storage machine 404 in a shared enclosure, or such display devices may be peripheral display devices.

When included, input subsystem 408 may comprise or interface with one or more user-input devices such as a keyboard, mouse, touch screen, or joystick. In some embodiments, the input subsystem may comprise or interface with selected natural user input (NUI) componentry. Such componentry may be integrated or peripheral, and the transduction and/or processing of input actions may be handled on- or off-board. Example NUI componentry may include a microphone for speech and/or voice recognition; an infrared, color, stereoscopic, and/or depth camera for machine vision and/or gesture recognition; a head tracker, eye tracker, accelerometer, and/or gyroscope for motion detection and/or intent recognition; as well as electric-field sensing componentry for assessing brain activity.

When included, communication subsystem 510 may be configured to communicatively couple computing system 400 with one or more other computing devices. Communication subsystem 510 may include wired and/or wireless communication devices compatible with one or more different communication protocols. As non-limiting examples, the communication subsystem may be configured for communication via a wireless telephone network, or a wired or wireless local- or wide-area network. In some embodiments, the communication subsystem may allow computing system 400 to send and/or receive messages to and/or from other devices via a network such as the Internet.

It will be understood that the configurations and/or approaches described herein are exemplary in nature, and that these specific embodiments or examples are not to be considered in a limiting sense, because numerous variations are possible. The specific routines or methods described herein may represent one or more of any number of processing strategies. As such, various acts illustrated and/or described may be performed in the sequence illustrated and/or described, in other sequences, in parallel, or omitted. Likewise, the order of the above-described processes may be changed.

The subject matter of the present disclosure includes all novel and nonobvious combinations and subcombinations of the various processes, systems and configurations, and other features, functions, acts, and/or properties disclosed herein, as well as any and all equivalents thereof.

1. A robot calibration system comprising:
a robot with an end-of-arm tool for industrial manufacturing;
an output sensor configured to measure an output of the robot; and
a computing device running a calibration program for calibrating an operation of the robot, the calibration program comprising:
a communication module configured to receive output data from the output sensor and status data from the robot; and
a control module configured to receive user input and to command the robot;
wherein the control module is configured to:
contact the robot to initiate calibration;
command actuation of the end-of-arm tool at an initial input value of an electrical parameter;
identify a current output value in the output data from the communication module;
determine that the current output value is not within a threshold of a target value;
execute an interpolation algorithm to calculate a next input value of the electrical parameter;
command actuation of the end-of-arm tool at the next input value;
identify a new current output value in the output data;
determine that the new current output value is within the threshold of the target value;
command the robot to end calibration;
log a relationship between input values of the electrical parameter and corresponding output values of the output data; and
make the logged relationship available to the robot to perform the calibrated operation according to the logged relationship.

2. The robot calibration system of claim 1, wherein the electrical parameter is an amperage, the output sensor is a force sensor, and the output data is force data.

3. The robot calibration system of claim 2, wherein the end-of-arm tool is a servo gun.

4. The robot calibration system of claim 1, wherein the user input is stored in advance to indicate the target value.

5. The robot calibration system of claim 1, wherein the robot is one of a plurality of robots contacted by the control module, the output sensor is one of a plurality of output sensors each associated with one of the plurality of robots, and the calibration of any of the plurality of robots overlaps in time.

6. The robot calibration system of claim 1, wherein the output data is a pressure, a temperature, a joint position, or a joint angle.

7. The robot calibration system of claim 1, wherein the interpolation algorithm calculates the next input value of the electrical parameter through tangential interpolation.

8. The robot calibration system of claim 1, wherein the computing device is a remote computing device connected to the robot via a network and a controller.

9. The robot calibration system of claim 1, wherein the computing device includes a processor, the processor being a central processing unit (CPU) or a system-on-chip.

10. The robot calibration system of claim 1, wherein the status data includes any of a joint angle, a joint position, a joint speed, a joint motor amperage, a robot position, and a robot speed.

11. A method of calibrating an operation of a robot with an end-of-arm tool for industrial manufacturing using a computing device running a calibration program, the method comprising:
contacting the robot to initiate calibration;
commanding actuation of the end-of-arm tool at an initial input value of an electrical parameter via a control module of the calibration program;
identifying a current output value of output data from a communication module of the calibration program, the output data generated by an output sensor to measure an output of the robot;
determining that the current output value is not within a threshold of a target value;
executing an interpolation algorithm to calculate a next input value of the electrical parameter;
commanding actuation of end-of-arm tool at the next input value;
identifying a new current output value in the output data;
determining that the new current output value is within the threshold of the target value;
commanding the robot to end calibration;
logging a relationship between input values of the electrical parameter and corresponding output values of the output data; and
making the logged relationship available to the robot to perform the calibrated operation according to the logged relationship.

12. The method of claim 11, wherein the electrical parameter is an amperage, the output sensor is a force sensor, and the output data is force data.

13. The method of claim 12, wherein the end-of-arm tool is a servo gun.

14. The method of claim 11, further comprising:
receiving user input indicating the target value;
storing the target value in memory of the computing device; and
upon initiation of calibration, retrieving the target value.

15. The method of claim 11, wherein the robot is one of a plurality of robots contacted by the control module, the output sensor is one of a plurality of output sensors each associated with one of the plurality of robots, and the calibration of any of the plurality of robots overlaps in time.

16. The method of claim 11, wherein the output data is a pressure, a temperature, a joint position, or a joint angle.

17. The method of claim 11, wherein the computing device is a remote computing device connected to the robot via a network and a controller.

18. The method of claim 11, wherein the computing device includes a processor, the processor being a central processing unit (CPU) or a system-on-chip.

19. The method of claim 11, further comprising receiving status data from the robot, the status data including any of a joint angle, a joint position, a joint speed, a joint motor amperage, a robot position, and a robot speed.

20. An automatic robot calibration system comprising:
a robot with an end-of-arm tool for industrial manufacturing, the end-of-arm tool being a servo gun;
an output sensor configured to measure an output of the robot; and
a computing device running a calibration program for calibrating an operation of the robot, the calibration program comprising:
a communication module configured to receive output data from the output sensor and status data from the robot, wherein the output data is force data; and
a control module configured to receive user input and to command the robot, wherein the user input is stored in advance to indicate a target value;
wherein the control module is configured to:
contact the robot to initiate calibration;
command actuation of the end-of-arm tool at an initial input value of an electrical parameter;
identify a current output value in the output data from the communication module;
determine that the current output value is not within a threshold of the target value;
execute an interpolation algorithm to calculate a next input value of the electrical parameter;
command actuation of the end-of-arm tool at the next input value;
identify a new current output value in the output data;
determine that the new current output value is within the threshold of the target value;
command the robot to end calibration;
log a relationship between input values of the electrical parameter and corresponding output values of the output data; and
make the logged relationship available to the robot to perform the calibrated operation according to the logged relationship.
